(19) United States
(12) Patent Application Publication
(10) Pub. No.: US 2025/0048784 A1
(43) Pub. Date: Feb. 6, 2025

(54) METHOD OF PROCESSING AN OPTOELECTRONIC DEVICE AND OPTOELECTRONIC DEVICE

(71) Applicant: ams-OSRAM International GmbH, Regensburg (DE)

(72) Inventors: Lutz Hoeppel, Alteglofsheim (DE); André Steiner, Dresden (DE); Vesna Mueller, Regensburg (DE); Markus Heyne, Regensburg (DE); Tobias Meyer, Kelheim (DE)

(21) Appl. No.: 18/717,384

(22) PCT Filed: Dec. 10, 2021
(86) PCT No.: PCT/EP2021/085301

§ 371 Date: Jun. 6, 2024

(51) Int. Cl. H01L 33/00

(52) U.S. Cl. CPC H01L 33/0075

(57) ABSTRACT

In embodiments a method includes providing a functional semiconductor layer stack and depositing a first material on the surface, in particular a transition element oxide. A structured hard mask stack is deposited on the first material, wherein the structured hard mask stack includes a first layer and at least a second layer on the first layer with sidewalls of at least the first layer covered by a second material, wherein the second layer and the second material are resilient against a wet chemical etching process. Two anisotropic dry chemical etching processes and a wet etching process is performed to provide a deep mesa structure in the functional layer stack, wherein the second layer protects the first layer during the wet etching process.

### CROSS-REFERENCE TO RELATED APPLICATIONS

This patent application is a national phase filing under section 371 of PCT/EP2021/085301, filed Dec. 10, 2021, which is incorporated herein by reference in its entirety.

### TECHNICAL FIELD

The present invention concerns a method for processing an optoelectronic device and an optoelectronic device.

### BACKGROUND

Optoelectronic devices with a diameter of its emitting surface of less than 70 μm and down to 1 μm are referred to as μ-LEDs. Such μ-LEDs have an emitting area of about 1 μm² to about 100 μm² and are configured to emit blue, red, and green light. The processing of such LEDs in a very small regime comprises various challenges. Some of those are related to the treatment of damaged side edges in particular of the active regions in order to stabilize and optimize the electro-optical performance of extremely small μ-LEDs. For this purpose, one has proposed using wet chemical etching processes to treat the dry-chemical side edges of the semiconductor layers, particularly in the area of the pn junction.

A suitable etchant for such a process is KOH. However, the usual mask material used for the dry etching process is not compatible with a wet etching process and vice versa. In addition, using layer materials resilient against wet etch processes like SiNx have properties that limit them for structuring and do not comprise the required selectivity during dry etching of mesa structures. Hence, more complex processes and mask layers must be utilized.

### SUMMARY

Embodiments provide various material stacks and propose a suitable process that allows for a highly selective etching process for both shallow and deep mesa etching alike.

With regard to structure size and shape of the μ-LEDs, the inventors propose to use only a single photolithographic step to structure the hard mask, which is subsequently utilized for the dry-etching and wet-etching processes. This approach enables a wet etching process by KOH only for the relevant vertically confined part of the mesa around the pn-junction.

In the process flow, the inventors propose to etch first a shallow mesa step with a suitable prepared hard mask, then apply KOH and subsequently etch to the final mesa depth while protecting the first mesa in the meantime. To enable this process, a mesa mask is required that is KOH stable and also comprises a high selectivity in a dry-etching process.

One of the best etch selectivity in a GaN dry etch process is provided by SiO2. However, SiO2 as such is not resilient against KOH and will be etched by the wet etchant used to clean the edges of the active region after the dry etching process. The inventors now propose to cover the exposed surfaces of a hard mask layer made of SiO2 in such a way that it will not be affected by the wet etching process often lasting for several minutes or even hours.

For this purpose, first the horizontal surface is covered with SiNx, while the side walls created in a previous structuring process are covered with a protective layer. A possible example for such a protective layer is HfO2 or another oxide of transition elements. SiNx can also be used as protective layer covering the sidewalls of SiO2 hard mask. When performing an anisotropic etch, the protective layer on the top surfaces is removed again but the cover on the sidewalls of the mask are not etched.

The above process allows for a relatively thin hard mask for the overall mesa-etching process because of the high selectivity of SiO2. The protection of the sidewalls of SiO2 by the protective layer material can be deposited as a very thin layer in the range of less than 30 nm, thus not significantly changing the lateral dimensions of the hard mask as such.

In an aspect a method of processing an optoelectronic device comprises the step of providing a functional semiconductor layer stack. The functional semiconductor layer stack includes an active region (12) that is buried beneath a surface of the functional semiconductor layer stack. A structured conductive layer is arranged on the surface of the layer stack. In this regard the conductive layer may comprise various properties and/or functionalities, including but not limited to providing a current distribution into a top layer of the functional layer stack. The conductive layer may comprise a transparent and/or a highly reflective metal.

Then, a first material is deposited onto the surface, in particular a transition element oxide covering the surface of the layer stack and the conductive layer. A structured hard mask stack is arranged on the first material, wherein the structured hard mask stack comprises a first layer and at least a second layer on the first layer. Sidewalls of at least the first layer are covered by a second material, said second material and the second layer being resilient against a wet chemical etching process. In other words, the first layer of the structured hard mask stack may be encapsulated by the second layer so that the material forms a protective layer.

In a subsequent step, a first anisotropic dry chemical etching process is performed, etching portions of the first material and the functional semiconductor layer stack not covered by the structured hard mask down to a first depth exposing edges of the active region. One may use a chlorine containing gas for this first dry etching process. Due to the anisotropic etching the sidewall is not etched but still protects the sidewalls of the hard mask. A wet chemical etching process is performed in a following step in particular to treat and shape the surfaces of the exposed functional semiconductor stack. During this wet etching process, the first layer of the hard mask stack is protected by the material on the sidewalls and the second layer on top of the first layer.

Once the wet etching process to remove damages from the mesa sidewalls and particularly from the edges of the active region is finished, the exposed edges of the active region are covered with a third material. Then, a second anisotropic dry chemical etching is performed removing portions of the functional semiconductor layer stack not covered by the structured hard mask and the third material to a second depth. Finally, the third material, the second material, and the first layer of the structured hard mask stack are removed, thereby exposing the first material.

The method according to the proposed principle combines the highly selective SiO2 hard mask layer with a protective encapsulation against the wet chemical process. This approach enables a manufacturing method without the need for providing an extra structuring process for the dry and wet etching processes. Rather, the structured mask layer stack acts as a mask layer for the various dry and wet etching processes.

In an aspect, the step of depositing a first material comprises depositing on the surface an oxide of a transition metal, in particular HfOx of a first configuration. The oxide of the transition metal covers the structured conductive layer as well as the surface of the functional semiconductor layer stack. In some further aspects, the first material might be very thin and may comprise a thickness in the range between 10 nm and 300 nm and in particular between 20 nm and 200 nm. Particularly certain transition metal oxides like HfOx can be applied using ALD or other deposition methods resulting in a very thin conformal layer. This is sufficient as such layers are resilient against KOH and also offer a suitable selectivity in anisotropic dry etching processes.

Some other aspects concern the step of depositing a structured hard mask stack. The first layer of said mask in particular containing SiO2 may be deposited on the first material and a second layer is arranged thereupon. The second layer comprising SiNx in some aspects. In some instances, the second layer comprises a smaller thickness than the first layer. For example, while the first layer may comprise a thickness in the range of 300 nm to 650 nm, the second layer is between 100 nm and 300 nm thick often in the range about 100 nm and 200 nm.

The first and the second layer are structured as to form a hard mask stack covering in some aspects the conductive layer and portions of the functional layer stack surrounding the conductive layer. In other words, the hard mask stack may be dry etched such that sidewalls are formed above portions of the functional semiconductor layer stack uncovered by the conductive layer stack. The second material is deposited on top portions of the structured mask as well as on sidewall portions of the first and second layer. In some aspects, the structured hard mask stack covers the conductive layer and portions of the functional layer stack surrounding the conductive layer.

The second material may comprise similar properties as the first material. In some aspects, the second material comprises an oxide of a transition metal, in particular HfOx of a second configuration. In this regard, HfOx can be formed as first and second material respectively using different precursors and/or different growth parameters. Possible precursors are O3 or H2O. The different precursors and/or different growth parameters result in different properties of HfOx such that the deposited layer exhibits different resilience against the etching with buffered HF or other buffered oxide etchant. Consequently, in some instances, the second material comprises a higher etching rate when exposed to a buffered oxide etch than the first material. The thickness of the second material may range from 10 nm to 70 nm and in particular from 15 nm to 30 nm.

In some further aspects, the second layer of the hard mask stack comprises SiNx with a thickness smaller than that for the first, particular SiO2 layer. SiNx is resilient against KOH and acts as a protective layer for the layer beneath during the wet etching process. In a subsequent step, a surface layer may be deposited onto the second layer. Said surface layer may comprise the same material as the first layer and can show a higher resilience against the first dry etching process than the SiNx layer. For example, the surface layer comprises SiO2.

In some further instances, the first layer is slightly recessed to form a bulge by the second layer. Consequently, the lateral extent of the first layer on the interface is smaller than the lateral extent of the second layer. The second material is then deposited onto the sidewalls of the first layer. The recess of the first layer is adjusted to at least half the thickness of the second material.

Consequently, the second layer of the structured hard mask stack and the second material encapsulate the first layer of the structured hard mask stack.

The first anisotropic dry etching process may cause inclined sidewalls in the functional layer stack exposing edges of the active region. The depth of the etching process can be controlled and may range between 300 nm and 1000 nm and in particular between 400 nm and 600 nm.

In another aspect, the wet chemical etching process comprises etching with KOH. After the wet etching process is finished, the exposed and treated edges and sidewalls of the active region are covered by a thin protective layer of a third material. Said third material may comprise Al2O3. It is deposited in some instance by a layer deposition process like ALD or also CVD with a thickness smaller than 30 nm and particularly than 10 nm. The third material layer protects the sidewalls and the edges of the active region from the subsequent dry etching process without damaging or interfering with the edges of the active region itself.

In some instances, the step of second anisotropic dry chemical etching is basically a repetition of the first dry etching process using the same etchant. Alternatively, a different etchant or different process parameter can be used to control the etch process. The second anisotropic dry chemical etching may remove the second layer of the structured hard mask stack, but only parts of the first layer of the hard mask. Thus, the structure beneath the hard mask stack is protected throughout the first dry etching process, the wet etching process using KOH and the subsequent second dry etching process.

In some further instances, the step of second anisotropic dry chemical etching causes inclined surface portions of the functional layer stack not covered by the third protective material. The inclination is different than the one on the sidewalls being treated by the wet etch process. In some aspects, second anisotropic dry chemical etching is performed until an undoped buffer layer of the functional layer stack is reached.

Finally, the residual of the third protective material is removed, for example using an acid, in which the third material is soluble. The second material as well as the first material of the hard mask stack is removed using a buffered oxide etchant. This last process will again expose the first material on top of the conductive layer and—in some instances—the surrounding portion if the functional layer stack. Due to the different configuration between the first material and the second material, the second material and the first layer of the hard mask stack are etched, while the first material is not significantly etched by the buffered oxide etch.

The present method can be applied to the processing of μ-LEDs based on various material systems including semiconductor material like GaN, InGaN and InAlGaN. These material systems do comprise a crystal orientation that is substantially inert to the wet chemical etching process for removing the hard mask.

Some other aspects relate to an optoelectronic device comprising a functional layer stack. The functional layer stack includes a first doped layer, a second doped layer and an active region located between the first doped layer and the second doped layer. A conductive layer is arranged on the surface of the second doped layer. The functional layer stack is processed to include a first sidewall extending along the second doped layer the active region and a first portion of the first doped layer. A second sidewall is located adjacent to the first sidewall. The second sidewall is laterally displaced to the first sidewall and extends along a second portion of the first doped layer. First portion and second portion may be adjacent to each other. An angle between the first sidewall portion and the second sidewall portion is larger than 0° and in particular between 1° and 10°.

The optoelectronic devices can be manufactured with the method in accordance with the proposed principle. In some aspects, the lateral displacement of the first and the second sidewalls and particularly of the first portion and the second portion causes a step having a thickness in the range smaller than 60 nm and in particular in the range between 10 nm and 40 nm. This step may be caused by and corresponds to the thickness of the third material deposited onto the first sidewall protecting the active region.

In some further aspects, the first sidewall is laterally displaced to the conductive layer on the surface of the second doped layer. Furthermore, the second sidewall comprises a thickness that is 4 to 6 times larger than a thickness of the first sidewall.

### BRIEF DESCRIPTION OF THE DRAWINGS

Further aspects and embodiments in accordance with the proposed principle will become apparent in relation to the various embodiments and examples described in detail in connection with the accompanying drawings in which

FIGS. 1A to 1C show the first steps of a method of processing an optoelectronic device in accordance with some aspects of the proposed principle;

FIGS. 2A to 2D illustrate further steps of a method of processing an optoelectronic device in accordance with some aspects of the proposed principle;

FIGS. 3A and 3B show some final steps of a method of processing an optoelectronic device in accordance with some aspects of the proposed principle; and

FIG. 4 illustrates an alternative embodiment of a method of processing an optoelectronic device in accordance with some aspects of the proposed principle.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

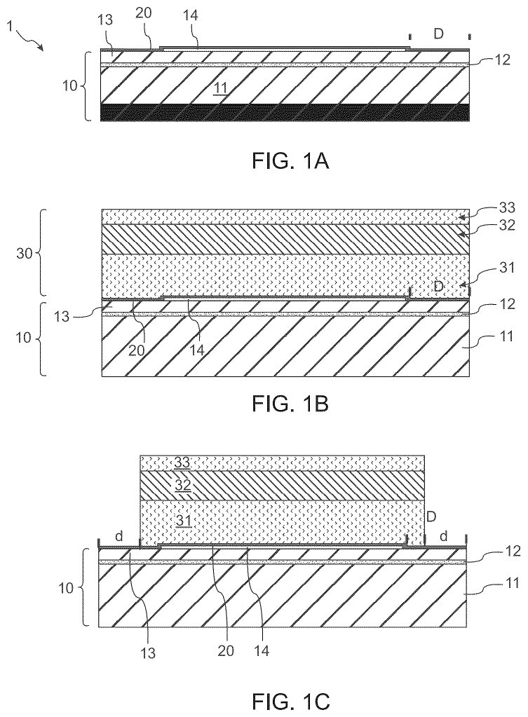

FIG. 1A to 1C illustrate the first few steps of a method for processing an optoelectronic device in accordance with some aspects of the proposed principle. The optoelectronic device also referred to as a μ-LED is configured to emit light of certain wavelengths, the way things may need depending on the base material used. The optoelectronic device one comprises a functional semiconductor layer stack 10 including several differently doped layers and an active region 12. The functional semiconductor layer stack is deposited on a growth substrate not shown that the embodiment including one or more of layer structures to prepare the deposition of the various layers of the layer stack 10.

More particularly, the functional semiconductor layer stack 10 comprises a first doped layer 11 in particular and n-doped layer directly deposited on the buffer layer structure or the growth substrate (not shown here), respectively. The n-doped first layer 11 may include a current distribution layer, a sacrificial layer or any other suitable layers providing current injection into an active region 12 deposited on the first doped layer 11. Active region 12 includes a quantum well structure or a multi-quantum well structure with a bandgap that is suitable to emit light of the desired wavelength.

Active region 13 may include quantum well intermixed areas in portions close to a Mesa structure processed in subsequent steps of the proposed method. On top of the active region 12 a second doped layer in particular a p-doped layer 13 is provided. In this regard, the second doped layer 13 as well as the first doped layer 11 may contain a constant doping profile or variable doping profile to ensure proper current injection into the active region 12 and achieve the desired electric characteristics.

A metal mirror structure 14 is provided on the top surface of second doped layer 13. Metal mirror structure 14 is conductive and contains a metal alloy including Silver and Zn for example. As illustrated in FIG. 1A metal mirror structure 14 covers a portion of the top surface of second layer 13 leaving areas D second doped layer 13 surrounding the mirror 14 exposed. Metal mirror structure 14 is utilized as a contact layer as well as the reflective layer for light being generated in the active region 12.

After depositing the various layers of the functional semiconductor layer stack 10 including the conductive metal mirror 14, a first protective layer 20 including first material is deposited on the conductive metal structure 14 as well as on the exposed surfaces of second doped layer 13. The material of layer 20 is particularly resilient against a wet etching process and may contain an oxide of a transition metal. A suitable oxide includes HfOx. The transition metal oxide is provided by offering two different precursors, one including the transition metal and the other one including oxygen. In this regard it should be noted that depending on the precursor of the oxygen as well as on the process parameters, i.e. the temperature during deposition, the transition metal oxide is deposited in a specific configuration. Said configuration will influence the etching behavior during the wet etching process. In other words, by selecting the various process parameter for the deposition process of layer 20, a configuration can be selected which inherits a different etching resilience against the wet etching process.

FIG. 1B illustrates the result of the deposition of a hard mask applied to the surface of protective layer 20. In a first sub step a SiO2 layer 31 having a thickness of about 500 nm is applied to the surface covering the protective layer 20. Layer 31 comprises a thickness in the range of about 500 nm. The SiO2 layer 31 is a highly selective material suitable for dry etching and enabling very precise structuring. A silicon nitride layer SiNx is deposited on top of the first layer 31. The silicon nitride layer 32 acts as a protective layer for first layer 31 during the wet etching process utilizing KOH. The thickness of layer 32 lies between 100 nm to 500 nm and is in the current example about 150 nm. While layer 32 is highly resilient against KOH during the wet etching process, it is however attacked and removed by a dry etching using gas containing Cl. Consequently, layer 32 is protected by another SiO2 layer 33 covering the surface of the silicon nitride layer. The protective layer 33 comprises a thickness of about 100 nm.

In a subsequent step illustrated in FIG. 1C, hard mask 30 including layers 31, 32 and 33 is structured to remove portions of the hard mask surrounding metal mirror structure 14 and portions of layer 20 surrounding the metal mirror 14. For this purpose, a photo mask material is applied to the top surface of layer 33, illuminated and a dry chemical etching process using CF3, CF4 or CxHyFz compound or SF6 together with an inert gas (e.g. Argon) is performed. The etching process removes the unexposed portions of the hard mask structure. As a result illustrated in FIG. 1C, surface areas of protective layer 20 with a thickness d are exposed and subsequently susceptible to the etching process.

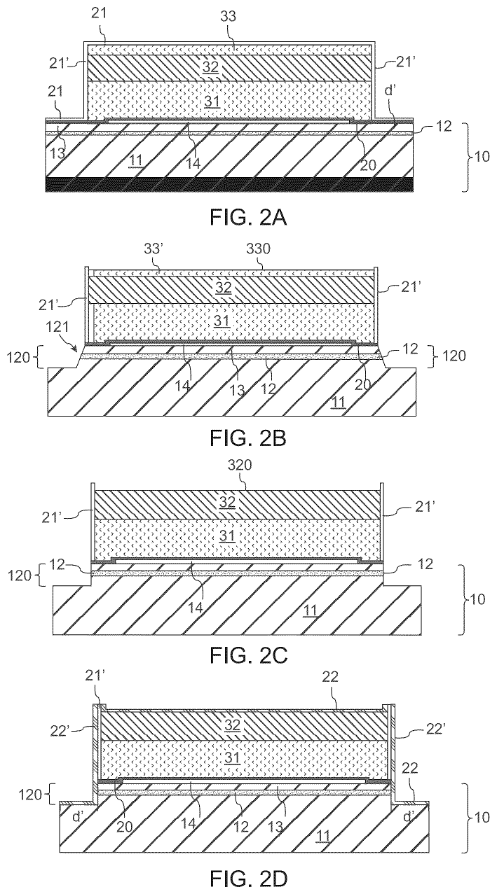

FIGS. 2A to 2D illustrate the next steps of the method of processing an optoelectronic device in accordance with the proposed principle. In FIG. 2A, a second protective layer 21 with the second material 21 is deposited on the top surface of layer 33 of hard mask stack 30 as well as on the sidewalls. The material 21′ on the sidewalls are covering layers 33 and 32 as well as layer 31 and extend again on the surface of first protective layer 20. The second material of the layer 21 is similar to the material of protective layer 20 with the exception that the configuration as indicated above is different. In other words, during the deposition of protective layer 21 either precursors or temperature is changed in comparison to the deposition of protective layer 20. This change is performed such that the etching rate of protective layer 21 is higher in a buffered oxide etchant compared to the protective layer 20. The different configuration will allow for later on removal of the protective layer 21 without affecting the first protective layer 20.

In a slightly alternative embodiment illustrated in FIG. 2A′, the first layer 31 is trimmed by a selective wet chemical etch step e.g. using KOH to obtain a small recess with respect to the second nitride layer 32. The depth of this recess is adjusted such that after applying second material 21″ on the sidewalls, the second material 21″ on the sidewalls of first layer 31 is flush with the sidewalls of layer 32.

Then, a first anisotropic dry etching process to obtain a shallow mesa structure is performed. The anisotropic dry etching process comprises a chlorine gas and will remove the top surfaces of protective layer 21 and 20, surrounding the structured hard mask 30. Protective layer 21 on top of the hard mask 30 is removed together with a small portion of the protective layer 33 containing SiO2. The remaining SiO2 material still protects the SiNx layer beneath. Exposed material of the functional semiconductor stack 10 including layers 13, the active region 12 and a portion of the first layer 11 is also etched to obtain a shallow mesa structure 120. The sidewalls 121 of the shallow mesa structure are slightly inclined due to the shadowing effects of the anisotropic dry etching process. The material 21′ applied on the sidewalls of hard mask structure 30 remains.

As a result of this first anisotropic dry etching process, side edges of active region 12 are exposed. The nature of the dry etching causes some damage to the crystal structure on the side edge of active region 12 as well as of region 13 and 11, leaving them with a high density of non-radiative recombination centers. To remove most of these non-radiative recombination centers, a wet etching process using KOH is performed. The wet etching process will expose well defined crystal facets preferable those that lead to practically vertical sidewalls 121, so that they are aligned with the sidewall of the structured hard mask. KOH is an etchant with a high etch rate for SiO2. Consequently, the remaining material of the first protective layer 33 is removed and the top surface of the SiNx layer 32 is exposed. However, the SiNx layer acts as a protective layer for the first layer 31 during the wet etching process. Furthermore, material 21′ on the sidewalls is also not affected by the wet etching process and KOH in particular. The resulting structure is illustrated in FIG. 2C.

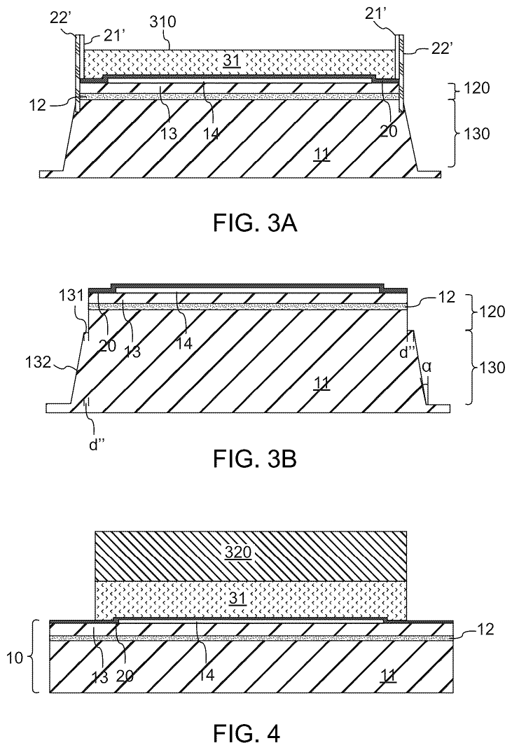

The exposed edges of the active region 12 are subsequently covered by the third material 22 after the wet etching process is finished. The third material comprises Al2O3. The material of layer 22 is deposited on the top surface of the SiNx layer 32 of hard mask 30 as well as on the top surface of the functional layer stack 30. The thickness is in the range of a few nanometers to 60 nm. The third material 22′ also extends on the sidewalls and on top of protective layer 21′. Layer 22′ protects the active region against the subsequent anisotropic dry etching process which is used to etch a deep mesa structure as illustrated in FIG. 3a.

The anisotropic dry etching process now removes layer 22 on top of layer 32 of hard mask 30 as well as the SiNx layer 32 down to the first SiO2 layer 31. In addition, the material of layer 22 on the top surface of the functional layer stack is removed and the functional layer stack etched until the undoped buffer layer is reached. As a result, inclined sidewalls are generated in the first doped layer 11 of the functional layer stack. The inclination of the sidewalls depends on the etchant as well as the process parameters thereof and is in the range of a few degrees. Due to the anisotropic etching process the sidewall layers 21′ and 22′ including HfO2 and Al2O3, respectively will remain protecting the surfaces of the functional layer stack in area 120 exposed during the first dry etching process.

After the second anisotropic dry etching process the protective layer material 22 is removed using a solution of H3PO4. Then a buffered oxide etchant is applied to remove protective layer material 21 and the SiO2 layer 31 until the first protective layer 20 is reached covering the metal structure 14 and the surrounding surface of the second doped layer 13, respectively. Due to the high resilience against the buffered oxide etchant (BOE) of the transition metal oxide 20, its surface is substantially left unetched and the layers beneath are protected. The removal of material 22 will leave a step edge 131 of width d″ between the first area 120 and the second area of the functional layer stack 130. Area 130 comprises the inclined sidewalls surfaces with an angle α in the range of a few degrees. The thickness of step edge 131 substantially corresponds to the thickness of the material layer 22′.

With the proposed method an optoelectronic device can be processed with a deep Mesa structure without changing the pattern mask during the overall process. In particular, the proposed structured hard mask on the surface protects the different layers against the dry and wet etching processes, respectively while at the same time enabling a very precise and selective etching process. Apart from the three-layered hard mask structure 30, an alternative way of processing an optoelectronic device is illustrated in FIG. 4.

This optoelectronic device comprises a functional layer stack 10 like the embodiment of the previously proposed method being covered by the first protective layer 20 on its surface. In contrast to the previous embodiment, hard mask structure layer 30 includes a first layer 31 made of SiO2, and a SiNx layer 320. However, the SiNx layer 320 comprises a substantially larger thickness compared to second layer 32 of the previous hard mask. This is because the protective third layer protecting the silicon nitride layer 320 is missing. Consequently, during the first anisotropic dry etching process the second nitride layer 320 is etched. It has been found that layer 320 may comprise a thickness in the range of 400 nm to 600 nm overall resulting in an even larger thickness for the hard mask. On the other hand, the deposition of the hard mask is simple due to the unnecessary additional protective layer.

1.-21. (canceled)

22. A method comprising:
providing a functional semiconductor layer stack comprising an active region spaced apart from a surface of the functional semiconductor layer stack, the surface comprising a structured conductive layer deposited thereon;
depositing a first material on the surface;
depositing a structured hard mask stack on the first material, wherein the structured hard mask stack comprises a first layer and at least a second layer on the first layer with sidewalls of at least the first layer covered by a second material, wherein the second layer and the second material are resilient against a wet chemical etching process;
first anisotropic dry chemical etching portions of the first material and the functional semiconductor layer stack not covered by the structured hard mask stack to a first depth exposing edges of the active region;
performing the wet chemical etching process on the exposed functional semiconductor stack;
covering the exposed edges of the active region with a third material;
second anisotropic dry chemical etching portions of the functional semiconductor layer stack not covered by the structured hard mask and the third material to a second depth; and
removing the third material, the second material, and the first layer of the structured hard mask stack thereby exposing the first material.

23. The method according to claim 22, wherein depositing the first material comprises depositing on the surface an oxide of a transition metal covering the structured conductive layer, the first material comprising a thickness in a range between 10 nm and 100 nm, inclusive.

24. The method according to claim 22, wherein depositing the structured hard mask stack comprises:
depositing the first layer on the first material;
depositing the second layer on the first layer, the second layer optionally having a smaller thickness than the first layer;
structuring the first and second layers by dry etching such that sidewalls are formed above portions of the functional semiconductor layer stack uncovered by the functional layer stack; and
depositing the second material on top portions of the structured mask as well as on sidewall portions of the first and second layers.

25. The method according to claim 24, wherein the second material comprises an oxide of a transition metal, the second material comprising a thickness on the sidewalls in a range of 10 nm to 70 nm, inclusive.

26. The method according to claim 24, wherein depositing the second layer comprises:
depositing a SiNx layer on the first layer comprising a thickness smaller than the first layer; and
depositing a surface layer onto the SiNx layer, the surface layer comprising the same material as the first layer.

27. The method according to claim 24, wherein depositing the second material comprises:
laterally recessing the first layer to form a bulge by the second layer; and
depositing the second material on the sidewalls of the first layer such as to compensate the bulge.

28. The method according to claim 24 wherein the second layer of the structured hard mask stack and the second material encapsulate the first layer of the structured hard mask stack.

29. The method according to claim 22, wherein the second material comprises a higher etching rate when exposed to a buffered oxide etch than the first material.

30. The method according to claim 22, wherein first anisotropic dry chemical etching causes inclined sidewalls in the functional layer stack.

31. The method according to claim 22, wherein the first depth is in a range between 300 nm and 1000 nm, inclusive.

32. The method according to claim 22, wherein the wet chemical etching process comprises etching with KOH.

33. The method according to claim 22, wherein covering the exposed edges of the active region comprises depositing the third material onto the sidewalls using an ALD process having a thickness in a range smaller than 60 nm.

34. The method according to claim 22, wherein second anisotropic dry chemical etching comprises the same etchant as the first anisotropic dry chemical etching, and/or wherein the second anisotropic dry chemical etching removes the second layer of the structured hard mask stack.

35. The method according to claim 22, wherein second anisotropic dry chemical etching causes inclined surface portions of the functional layer stack not covered by the third material.

36. The method according to claim 22, wherein second anisotropic dry chemical etching is performed until an undoped buffer layer of the functional layer stack is reached.

37. The method according to claim 22, wherein removing the third material, the second material, and the first layer of the structured hard mask stack comprises two different wet etch processes, one being a buffered oxide etch.

38. The method according to claim 22, wherein the functional layer stack comprises a semiconductor material from a group consisting of GaN, InGaN, and InAlGaN,
and wherein optionally a crystal orientation of the semiconductor material is substantially inert to the wet chemical etching process.

39. An optoelectronic device comprising:
a functional layer stack comprising:
a first doped layer;
a second doped layer;
an active region between the first doped layer and the second doped layer; and
a conductive layer on a surface of the second doped layer;
a first sidewall extending along the second doped layer the active region and a first portion of the first doped layer; and
a second sidewall laterally displaced to the first sidewall and extending along a second portion of the first doped layer,
wherein an angle between the first sidewall and the second sidewall is larger than 0°.

40. The optoelectronic device according to claim 39, wherein a lateral displacement of the first and the second sidewalls causes a step having a thickness in a range smaller than 60 nm.

41. The optoelectronic device according to claim 39, wherein the first sidewall is laterally displaced to the conductive layer on the surface of the second doped layer.

42. The optoelectronic device according to claim 39, wherein the second sidewall comprises a thickness that is 4 to 6 times larger than a thickness of the first sidewall.
